(19) United States
(12) Patent Application Publication
(10) Pub. No.: US 2014/0283994 A1
(43) Pub. Date: Sep. 25, 2014

(54) APPARATUS FOR TREATING SURFACES OF WAFER-SHAPED ARTICLES

(71) Applicant: LAM RESEARCH AG, Villach (AT)

(72) Inventor: Andreas GLEISSNER, DOBRIACH (AT)

(73) Assignee: LAM RESEARCH AG, Villach (AT)

(21) Appl. No.: 13/849,202

(22) Filed: Mar. 22, 2013

(51) Int. Cl. H01L 21/67

(52) U.S. Cl. CPC H01L 21/67023
USPC 156/345.23; 134/104.2

(57) ABSTRACT

An apparatus for liquid treatment of substrates, comprises a substrate holder and a liquid collector surrounding the substrate holder. The liquid collector comprises a trough for collecting liquid that has been used to treat a substrate. The trough is in fluid communication with a discharge conduit, and the liquid collector further comprising a recessed surface extending from a discharge opening in the trough to an inlet opening of the discharge conduit that is positioned lower than the trough. The discharge opening in the trough has a cross-sectional area that is at least twice as large in cross sectional area than the inlet opening of the discharge conduit.

### BACKGROUND OF THE INVENTION

1. Field of the Invention

The invention relates generally to an apparatus for treating surfaces of wafer-shaped articles, such as semiconductor wafers, wherein one or more treatment fluids may be recovered from within a closed process chamber.

2. Description of Related Art

Semiconductor wafers are subjected to various surface treatment processes such as etching, cleaning, polishing and material deposition. To accommodate such processes, a single wafer may be supported in relation to one or more treatment fluid nozzles by a chuck associated with a rotatable carrier, as is described for example in U.S. Pat. Nos. 4,903,717 and 5,513,668.

Alternatively, a chuck in the form of a ring rotor adapted to support a wafer may be located within a closed process chamber and driven without physical contact through an active magnetic bearing, as is described for example in International Publication No. WO 2007/101764 and U.S. Pat. No. 6,485,531. Treatment fluids which are driven outwardly from the edge of a rotating wafer due to centrifugal action are delivered to a common drain for disposal.

An improved closed process chamber is described in commonly-owned co-pending application U.S. Pub. No. 2013/0062839. The present inventor has discovered, however, that used process liquid is not always fully recovered from a process chamber as described in that patent application. In particular, the present inventor discovered that the air currents generated by the spinning chuck caused turbulence in the process liquid that was gathered in the drainage channel of the surrounding chamber, resulting in splashing of the process liquid and adhesion of droplets of used process liquid to other interior surfaces of the process chamber.

### SUMMARY OF THE INVENTION

Thus, the invention in one aspect relates to an apparatus for liquid treatment of substrates, comprising a substrate holder and a liquid collector surrounding the substrate holder. The liquid collector comprises a trough for collecting liquid that has been used to treat a substrate. The trough is in fluid communication with a discharge conduit, and the liquid collector further comprising a recessed surface extending from a discharge opening in the trough to an inlet opening of the discharge conduit that is positioned lower than the trough. The discharge opening in the trough has a cross-sectional area that is at least twice as large in cross sectional area as the inlet opening of the discharge conduit.

In preferred embodiments of the apparatus according to the present invention, the holder and the liquid collector are present within a process chamber that can be sealed during liquid treatment of a substrate.

In preferred embodiments of the apparatus according to the present invention, the holder is a spin chuck for holding and rotating a wafer-shaped article.

In preferred embodiments of the apparatus according to the present invention, the holder is a chuck driven in rotation by a shaft, and the chuck comprises a circular series of pins positioned so as to contact an edge region of a substrate.

In preferred embodiments of the apparatus according to the present invention, the holder is a magnetic rotor ring driven in rotation by a surrounding electromagnetic stator, and the magnetic rotor ring comprises a circular series of pins depending downwardly from the magnetic rotor ring and positioned so as to contact an edge region of a substrate.

In preferred embodiments of the apparatus according to the present invention, wherein the recessed surface comprises a pair of elongated depressions extending along the trough on opposite sides of the inlet opening of the discharge conduit.

In preferred embodiments of the apparatus according to the present invention, the inlet opening of the discharge conduit is uncovered and is surrounded in plan view by the discharge opening in the trough.

In preferred embodiments of the apparatus according to the present invention, the discharge opening in the trough has a cross-sectional area that is at least three times as large in cross sectional area as the inlet opening of the discharge conduit.

In preferred embodiments of the apparatus according to the present invention, the discharge opening in the trough has a cross-sectional area that is at least four times as large in cross sectional area as the inlet opening of the discharge conduit.

In preferred embodiments of the apparatus according to the present invention, the recessed surface forms an edge with the trough at the discharge opening in the trough.

In preferred embodiments of the apparatus according to the present invention, the recessed surface further comprises a pair of secondary recesses extending on opposite sides of the inlet opening of the discharge conduit and generally along the trough.

In another aspect, the present invention relates to a liquid collector for use in apparatus for liquid treatment of substrates. The liquid collector comprises a housing having an internal peripheral trough for collecting liquid used to treat a substrate. The trough is in fluid communication with a discharge conduit, and the liquid collector further comprises a recessed surface extending from a discharge opening in the trough to an inlet opening of the discharge conduit that is positioned lower than the trough. The discharge opening in the trough has a cross-sectional area that is at least twice as large in cross sectional area as the inlet opening of the discharge conduit.

In preferred embodiments of the liquid collector according to the present invention, the recessed area comprises a pair of elongated depressions extending along the trough on opposite sides of the inlet opening of the discharge conduit.

In preferred embodiments of the liquid collector according to the present invention, the inlet opening of the discharge conduit is uncovered and is surrounded in plan view by the discharge opening in the trough.

In preferred embodiments of the liquid collector according to the present invention, the discharge opening in the trough has a cross-sectional area that is at least three times as large in cross sectional area as the inlet opening of the discharge conduit.

In preferred embodiments of the liquid collector according to the present invention, the discharge opening in the trough has a cross-sectional area that is at least four times as large in cross sectional area as the inlet opening of the discharge conduit.

In preferred embodiments of the liquid collector according to the present invention, the recessed surface further comprises a pair of secondary recesses extending on opposite sides of the inlet opening of the discharge conduit and generally along the trough.

### BRIEF DESCRIPTION OF THE DRAWINGS

Other objects, features and advantages of the invention will become more apparent after reading the following detailed description of preferred embodiments of the invention, given with reference to the accompanying drawings, in which:

FIG. 1 is an explanatory cross-sectional side view of a process chamber according to a first embodiment of the invention, with the interior cover shown in its first position;

FIG. 2 is an explanatory cross-sectional side view of a process chamber according to the first embodiment of the invention, with the interior cover shown in its second position;

FIG. 3 is an enlarged view of the detail III in FIG. 1;

FIG. 4 is an explanatory cross-sectional perspective view of the liquid collector of the embodiment shown in FIGS. 1 and 2;

FIG. 5 is a perspective view from above of the liquid collector of the embodiment shown in FIGS. 1 and 2; and

FIG. 6 is an enlarged view of the detail XI in FIG. 5.

### DETAILED DESCRIPTION OF PREFERRED EMBODIMENTS

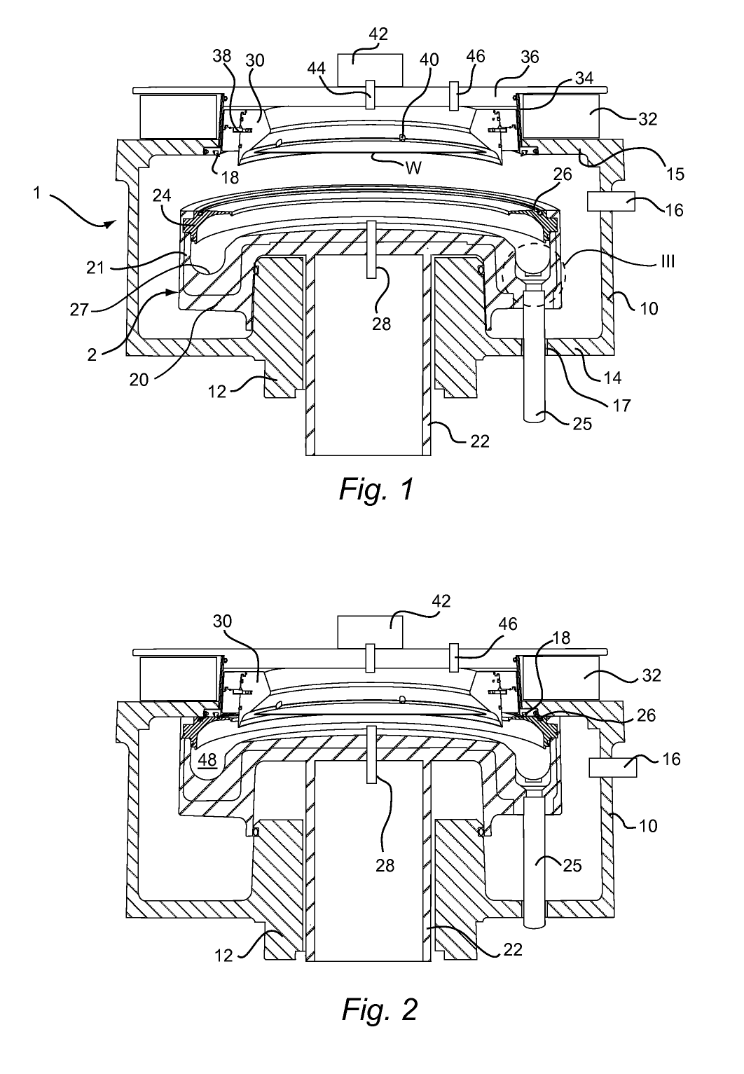

Referring now to FIG. 1, an apparatus for treating surfaces of wafer-shaped articles according to a first embodiment of the invention comprises an outer process chamber 1, which is preferably made of aluminum coated with PFA (perfluoroalkoxy) resin. The chamber in this embodiment has a main cylindrical wall 10, a lower part 12 and an upper part 15. From upper part 15 there extends a narrower cylindrical wall 34, which is closed by a lid 36.

A rotary chuck 30 is disposed in the upper part of chamber 1, and surrounded by the cylindrical wall 34. Rotary chuck 30 rotatably supports a wafer W during use of the apparatus. The rotary chuck 30 incorporates a rotary drive comprising ring gear 38, which engages and drives a plurality of eccentrically movable gripping members for selectively contacting and releasing the peripheral edge of a wafer W.

In this embodiment, the rotary chuck 30 is a ring rotor provided adjacent to the interior surface of the cylindrical wall 34. A stator 32 is provided opposite the ring rotor adjacent the outer surface of the cylindrical wall 34. The rotor 30 and stator 34 serve as a motor by which the ring rotor 30 (and thereby a supported wafer W) may be rotated through an active magnetic bearing. For example, the stator 34 can comprise a plurality of electromagnetic coils or windings that may be actively controlled to rotatably drive the rotary chuck 30 through corresponding permanent magnets provided on the rotor. Axial and radial bearing of the rotary chuck 30 may be accomplished also by active control of the stator or by permanent magnets. Thus, the rotary chuck 30 may be levitated and rotatably driven free from mechanical contact. Alternatively, the rotor may be held by a passive bearing where the magnets of the rotor are held by corresponding high-temperature-superconducting magnets (HTS-magnets) that are circumferentially arranged on an outer rotor outside the chamber. With this alternative embodiment each magnet of the ring rotor is pinned to its corresponding HTS-magnet of the outer rotor. Therefore the inner rotor makes the same movement as the outer rotor without being physically connected.

The lid 36 has a manifold 42 mounted on its exterior, which supplies a medium inlet 44 that traverses the lid 36 and opens into the chamber above the wafer W. It will be noted that the wafer W in this embodiment hangs downwardly from the rotary chuck 30, supported by the gripping members 40, such that fluids supplied through inlet 44 would impinge upon the upwardly facing surface of the wafer W.

In case wafer 30 is a semiconductor wafer, for example of 300 mm or 450 mm diameter, the upwardly facing side of wafer W could be either the device side or the obverse side of the wafer W, which is determined by how the wafer is positioned on the rotary chuck 30, which in turn is dictated by the particular process being performed within the chamber 1.

The apparatus of FIG. 1 further comprises an interior cover 2, which is movable relative to the process chamber 1. Interior cover 2 is shown in FIG. 1 in its first, or open, position, in which the rotary chuck 30 is in communication with the outer cylindrical wall 10 of chamber 1.

Cover 2 in this embodiment is generally cup-shaped, comprising a base 20 surrounded by an upstanding cylindrical wall 21, which together also constitute a collector for used process liquids. The collector includes an annular trough 27, where used process liquid collects and from which used process liquid is led to a discharge conduit 25. Cover 2 furthermore comprises a hollow shaft 22 supporting the base 20, and traversing the lower wall 14 of the chamber 1.

Hollow shaft 22 is surrounded by a boss 12 formed in the main chamber 1, and these elements are connected via a dynamic seal that permits the hollow shaft 22 to be displaced relative to the boss 12 while maintaining a gas-tight seal with the chamber 1.

At the top of cylindrical wall 21 there is attached an annular deflector member 24, which carries on its upwardly-facing surface a gasket 26. Cover 2 preferably comprises at least one fluid medium inlet 28 traversing the base 20, so that process fluids and rinsing liquid may be introduced into the chamber onto the downwardly facing surface of wafer W.

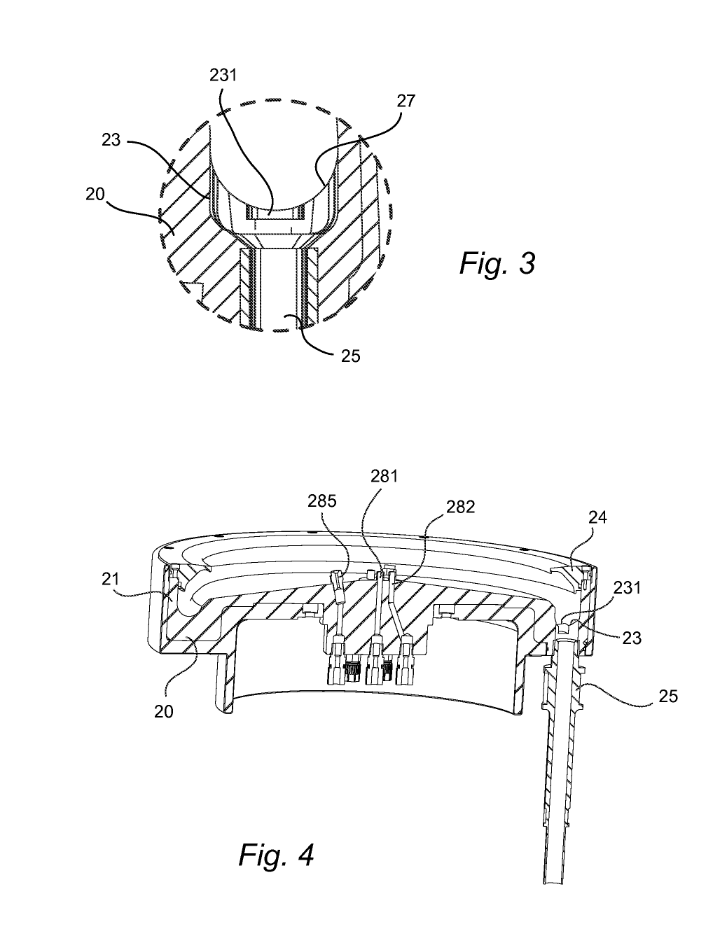

Cover 2 furthermore includes a process liquid discharge opening 23, which directs used process liquid into discharge pipe 25, as will be described more fully in connection with FIG. 3. Whereas pipe 25 is rigidly mounted to base 20 of cover 2, it traverses the bottom wall 14 of chamber 1 via a dynamic seal 17 so that the pipe may slide axially relative to the bottom wall 14 while maintaining a gas-tight seal.

An exhaust opening 16 traverses the wall 10 of chamber 1, whereas a separate exhaust opening 46 traverses the lid 36 near the inner surface of rotary chuck 30. Each exhaust opening is connected to suitable exhaust conduits (not shown), which are preferably independently controlled via respective valves and venting devices.

The position depicted in FIG. 1 corresponds to loading or unloading of a wafer W. In particular, a wafer W can be loaded onto the rotary chuck 30 either through the lid 36, or, more preferably, through a side door (not shown) in the chamber wall 10. However, when the lid 36 is in position and when any side door has been closed, the chamber 1 is gas-tight and able to maintain a defined internal pressure.

In FIG. 2, the interior cover 2 has been moved to its second, or closed, position, which corresponds to processing of a wafer W. That is, after a wafer W is loaded onto rotary chuck 30, the cover 2 is moved upwardly relative to chamber 1, by a suitable motor (not shown) acting upon the hollow shaft 22. The upward movement of the interior cover 2 continues until the deflector member 24 comes into contact with the interior surface of the upper part 15 of chamber 1. In particular, the gasket 26 carried by deflector 24 seals against the underside of upper part 15, whereas the gasket 18 carried by the upper part 15 seals against the upper surface of deflector 24.

When the interior cover 2 reaches its second position as depicted in FIG. 2, there is thus created a second chamber 48 within the closed process chamber 1. Inner chamber 48 is moreover sealed in a gas tight manner from the remainder of the chamber 1. Moreover, the chamber 48 is preferably separately vented from the remainder of chamber 1, which is achieved in this embodiment by the provision of the exhaust port 46 opening into the chamber 48, independently from the exhaust port 16 that serves the chamber 1 in general, and the remainder of the chamber 1 in the FIG. 2 configuration.

During processing of a wafer, processing fluids may be directed through medium inlets 44 and/or 28 to a rotating wafer W in order to perform various processes, such as etching, cleaning, rinsing, and any other desired surface treatment of the wafer undergoing processing.

In alternative embodiments, the cover 2 may be equipped with vertically movable splash guard and plural concentric drainage troughs, as shown in FIGS. 3-6 of commonly-owned co-pending application U.S. Pub. No. 2013/0062839. In further alternative embodiments, the magnetic rotor chuck 30 may be replaced by a shaft-driven chuck as shown in FIGS. 7-10 of commonly-owned co-pending application U.S. Pub. No. 2013/0062839.

Referring now to FIG. 3, shown therein is the transitional recessed surface that connects the trough 27 to the discharge conduit 25. In particular, trough 27, which is approximately part-circular in cross-section in this embodiment, has an opening 23 formed therein, which leads, via inwardly sloping recessed surfaces, to the inlet of discharge conduit 25. Discharge opening 23 is substantially larger in cross-sectional area than the discharge conduit 25, and in particular, it is at least two times larger in cross-sectional area, preferably at least three times larger, and more preferably at least four times larger.

Moreover, the recessed volume beneath the trough 27 and above the discharge conduit 25 is further increased by a pair of slots or secondary recesses 231 formed on either side of the discharge conduit, and extending in a direction generally perpendicular to the plane of the drawing in FIG. 3, only one of which secondary recesses 231 is visible in FIG. 3.

The distance from the bottom of trough 27 to the inlet of discharge conduit 25 is preferably at least 3 mm measured vertically.

This structure serves to provide a secondary collection reservoir for used process liquid that is downstream of the trough 27 and upstream of the discharge conduit 25. Importantly, this recessed volume is much more protected from the often strong air or gas currents that are created by the rapidly rotating chuck. Therefore, this structure is effective to prevent splashing of the used process liquid as can occur in the earlier patent application described above, and the used process liquid instead flows smoothly from the trough 27 into the discharge conduit 25.

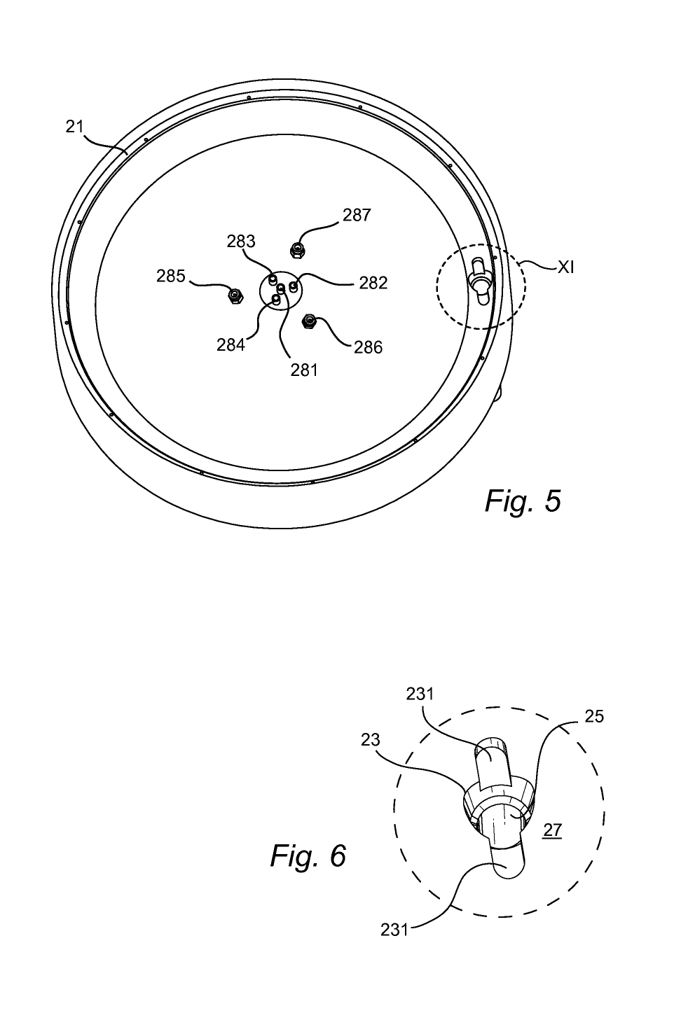

As shown in FIG. 4, the collector structure preferably includes multiple liquid conduits 281, 282 and gas conduits 285, so as to supply a variety of chemical compositions, rinse liquid, and inert gases to the downwardly-facing side of the wafer W. These are better seen in FIG. 5, as liquid conduits 281-284 and gas conduits 285-287.

FIG. 6 more fully shows the contour of the recessed transitional surface and the recessed volume defined thereby, according to this embodiment. The bottom of the trough 27 generally conforms to the lower half of a torus. The recessed surfaces join the bottom of trough 27 at the discharge opening 23, in such a manner that the surfaces change direction abruptly, so as to form a relatively sharp edge at the discharge opening.

This sharp edge promotes the flow of air currents along the toroidal surface of the trough 27, and minimizes air currents entering into the recessed volume. The secondary recesses 231 of the recessed surface are provided so as to increase the total volume available to the used process liquid beneath the trough 27 and above the discharge conduit 25, there being more room for such secondary recesses 231 in the circumferential direction of trough 27, but much less so in the radial direction thereof.

This structure therefore alleviates the splashing problem described in connection with the predecessor design, improves recovery of used process fluid from the collector, and improves the flow rate of process liquid through the collector.

It should also be noted that, although the improved handling of used process liquid according to the present invention is preferably applied to a closed process chamber as shown in the accompanying drawings, it may also be applied to open processing units, such as a spin chuck surrounded by an open collector having vertically superposed process levels as described for example in U.S. Pat. No. 4,903,717.

While the present invention has been described in connection with various preferred embodiments thereof, it is to be understood that those embodiments are provided merely to illustrate the invention, and should not be used as a pretext to limit the scope of protection conferred by the true scope and spirit of the appended claims.

What is claimed is:

1. An apparatus for liquid treatment of substrates, comprising a substrate holder and a liquid collector surrounding the substrate holder, the liquid collector comprising a trough for collecting liquid that has been used to treat a substrate, the trough being in fluid communication with a discharge conduit, said liquid collector further comprising a recessed surface extending from a discharge opening in said trough to an inlet opening of said discharge conduit that is positioned lower than said trough, wherein said discharge opening in said trough has a cross-sectional area that is at least twice as large in cross sectional area as said inlet opening of said discharge conduit.

2. The apparatus according to claim 1, wherein said holder and said liquid collector are present within a process chamber that can be sealed during liquid treatment of a substrate.

3. The apparatus according to claim 1, wherein said holder is a spin chuck for holding and rotating a wafer-shaped article.

4. The apparatus according to claim 1, wherein said holder is a chuck driven in rotation by a shaft, and wherein said chuck comprises a circular series of pins positioned so as to contact an edge region of a substrate.

5. The apparatus according to claim 1, wherein said holder is a magnetic rotor ring driven in rotation by a surrounding electromagnetic stator, wherein said magnetic rotor ring comprises a circular series of pins depending downwardly from said magnetic rotor ring and positioned so as to contact an edge region of a substrate.

6. The apparatus according to claim 1, wherein said recessed surface comprises a pair of elongated depressions extending along said trough on opposite sides of said inlet opening of said discharge conduit.

7. The apparatus according to claim 1, wherein said inlet opening of said discharge conduit is uncovered and is surrounded in plan view by said discharge opening in said trough.

8. The apparatus according to claim 1, wherein said discharge opening in said trough has a cross-sectional area that is at least three times as large in cross sectional area as said inlet opening of said discharge conduit.

9. The apparatus according to claim 1, wherein said discharge opening in said trough has a cross-sectional area that is at least four times as large in cross sectional area as said inlet opening of said discharge conduit.

10. The apparatus according to claim 1, wherein said recessed surface forms an edge with said trough at said discharge opening in said trough.

11. The apparatus according to claim 1, wherein said recessed surface further comprises a pair of secondary recesses extending on opposite sides of said inlet opening of said discharge conduit and generally along said trough.

12. A liquid collector for use in apparatus for liquid treatment of substrates, said liquid collector comprising a housing having an internal peripheral trough for collecting liquid used to treat a substrate, the trough being in fluid communication with a discharge conduit, said liquid collector further comprising a recessed surface extending from a discharge opening in said trough to an inlet opening of said discharge conduit that is positioned lower than said trough, wherein said discharge opening in said trough has a cross-sectional area that is at least twice as large in cross sectional area as said inlet opening of said discharge conduit.

13. The liquid collector according to claim 12, wherein said recessed area comprises a pair of elongated depressions extending along said trough on opposite sides of said inlet opening of said discharge conduit.

14. The liquid collector according to claim 12, wherein said inlet opening of said discharge conduit is uncovered and is surrounded in plan view by said discharge opening in said trough.

15. The liquid collector according to claim 12, wherein said discharge opening in said trough has a cross-sectional area that is at least three times as large in cross sectional area as said inlet opening of said discharge conduit.

16. The liquid collector according to claim 12, wherein said discharge opening in said trough has a cross-sectional area that is at least four times as large in cross sectional area as said inlet opening of said discharge conduit.

17. The liquid collector according to claim 12, wherein said recessed surface further comprises a pair of secondary recesses extending on opposite sides of said inlet opening of said discharge conduit and generally along said trough.
